(19) United States
(12) Patent Application Publication
(10) Pub. No.: US 2026/0299401 A1
(43) Pub. Date: Oct. 1, 2026

(54) RETICLE DESIGN FOR MINIMIZING THERMAL STRAIN

(71) Applicant: ASML Netherlands B.V., Veldhoven (NL)

(72) Inventors: Lowell Lane BAKER, Norwalk, CT (US); Ksenia Sergeevna MAKARENKO, Ridgefield, CT (US); Nathan Robert FINNEY, Trumbull, CT (US); Jacobus Cornelis Gerardus VAN DER SANDEN, Geldrop (NL); James MELFI, JR., Norwalk, CT (US); Marcus Adrianus VAN DE KERKHOF, Helmond (NL); Daniel Andreas DEENEN, Eindhoven (NL); Matthew LIPSON, Stamford, CT (US); Justin RADEMAKER, Tull en ‘t Waal (NL)

(73) Assignee: ASML Netherlands B.V., Veldhoven (NL)

(21) Appl. No.: 19/490,151

(22) PCT Filed: Jun. 5, 2024
(86) PCT No.: PCT/EP2024/065507

§ 371 Date: Dec. 4, 2025

Related U.S. Application Data
(60) Provisional application No. 63/522,581, filed on Jun. 22, 2023.

(51) Int. Cl. G03F 1/70; G03F 1/22

(52) U.S. Cl. CPC G03F 1/70; G03F 1/22

(57) ABSTRACT

A method for reducing thermal strain in a reticle includes determining a target operating temperature of a reticle during use of the reticle, adjusting a thermal expansion (TE) property of the reticle based on the target operating temperature of the reticle, and exposing the reticle to radiation to perform a manufacturing process.

### CROSS REFERENCE TO RELATED APPLICATION

This application claims priority to U.S. Application No. 63/522,581, filed Jun. 22, 2023, and which is incorporated herein in its entirety by reference.

### FIELD

The present disclosure relates to treatment and conditioning of reticles, for example, controlling thermal expansion properties of a reticle in lithography apparatuses and systems.

### BACKGROUND

A lithographic apparatus is a machine constructed to apply a desired pattern onto a substrate. A lithographic apparatus can be used, for example, in the manufacture of integrated circuits (ICs). A lithographic apparatus can, for example, project a pattern of a patterning device (e.g., a mask, a reticle) onto a layer of radiation-sensitive material (photoresist or simply “resist”) provided on a substrate.

To project a pattern on a substrate a lithographic apparatus can use electromagnetic radiation. The wavelength of this radiation determines the minimum size of features that can be formed on the substrate. A lithographic apparatus, which uses extreme ultraviolet (EUV) radiation, having a wavelength within the range 4-20 nm, for example 6.7 nm or 13.5 nm, can be used to form smaller features on a substrate than a lithographic apparatus which uses, for example, radiation with a wavelength of 193 nm.

A lithographic apparatus may include a patterning device (e.g. a mask or reticle). Radiation can be provided through or reflected off the patterning device to form an image on a substrate. A membrane assembly, also referred to as a pellicle, can be provided to protect the patterning device from airborne particles and other forms of contamination. Contamination on the surface of the patterning device can cause manufacturing defects on the substrate.

During use, the reticle can be exposed to a beam of radiation, which causes the reticle to heat up. In order to manage the temperature of the reticle, the reticle can be provided with cooling, which can be in the form of liquid cooling. The reticle can be supported by a reticle clamp that holds the reticle in place. Even though the temperature of the reticle can be controlled, the shape of the reticle changes upon exposure to the radiation beam, which can cause deformation of the reticle, leading to overlay issues. While some deformation can be corrected by alignment adjustments, there remains parts of the deformation that cannot be corrected by existing methods, and are therefore non-correctable.

Reticles used for lithographic wafer processing are subject to conflicting heating and cooling during use. For example, a reticle may be subject to local heating (e.g., from the radiation used in the wafer processing heating a portion of the reticle) and local cooling (e.g., from contact with a chuck or clamp that is actively cooled to avoid overheating). In addition, a reticle may also be subject to large temperature swings during use, being heated from an initial temperature that is near room temperature to an operating temperature that is substantially higher than room temperature. As a result, during exposure of the reticle to perform wafer processing, the reticle can be subject to a large thermal strain, leading to an overlay error.

As particular examples, the temperature of the reticle may change dramatically during the exposure of the first several wafers of a processing lot of wafers. Thus, the latter wafers in the lot will have a hotter reticle than the first, leading to “intra-lot” overlay error. Similar effects can also be seen for different fields within the same wafer, such that the last fields of a wafer will have a hotter reticle than the first ones, leading to “intra-wafer” overlay error. Such temperature changes in the reticle during exposure cause a thermal strain in the reticle, which can lead to in-plane and out-of-plane deformations of the reticle as well as the potential for slip. These problems can be exacerbated when the wafer processing requires that reticles be switched more often.

Reticle alignment modeling provides only limited corrections to the above problems. Further methods of reducing a thermally induced overlay error are required.

### SUMMARY

Accordingly, it is desirable to reduce a thermal strain experienced by the reticle during use, to thereby reduce the resulting overlay error. As discussed below, the reticle and one or more thermal expansion (TE) properties of the reticle may be adjusted based on a target operating temperature of the reticle.

In some aspects, a reticle or a reticle blank can comprise a low deformation material, wherein the reticle or reticle blank material has a Zero Crossing Temperature (ZCT) profile, and a ZCT slope profile, wherein at least one of the ZCT profile and the ZCT slope profile is non-uniform.

Reticles and reticle blanks for use in lithographic apparatus and processes can comprise ultra-low expansion (ULE) glass. ULE can be used because its shape changes by only a small amount compared to other materials when its temperature changes. In use, the ULE glass can be heated by absorbing a large amount of energy from the radiation beam. Cooling can be used to control the temperature of the reticle, although some degree of heating may still occur. The reticles can be supported by a reticle clamp, and thus the reticle can deform when constrained by the clamp. Although some of these deformations are correctable by aligning the reticle using fiducial marks on the reticle, higher-order deformations are non-correctable by existing means.

Some aspects of this disclosure address this shortcoming by providing a reticle or reticle blank for which one or both of the zero-crossing temperature profile and the ZCT slope profile are non-uniform. The zero-crossing temperature is the temperature at which, or the temperature range over which, a thermal expansion of the material comprising the reticle crosses zero. Some materials, such as, for example, ULE glass, have a temperature or temperature range where the coefficient of thermal expansion crosses zero. Around the zero-crossing temperature, the material is dimensionally stable to temperature fluctuations. The zero-crossing temperature slope is the rate at which the coefficient of thermal expansion changes around the zero crossing temperature. Existing reticles and reticle blanks are manufactured to have as uniform a ZCT profile as possible. The ZCT slope profile is based on the length of the annealing process of the material used to form the reticle or reticle blank. This can lead to in-use deformations that are non-correctable. Some embodiments of this disclosure provide for a reticle or reticle blank having a non-uniform ZCT profile and/or ZCT slope profile such that different parts of the reticle or reticle blank deform in different ways in use. This allows for the reticle or reticle blank to be configured to have different deformation characteristics in use and to limit the degree of non-correctable deformations.

The reticle or reticle blank has x, y, and z-directions. In some aspects, at least one of the ZCT profile and ZCT slope profile can vary in the y-direction. The ZCT profile and/or ZCT slope profile in the y-direction can be configured such that it is a lower-order profile, such as a quadratic profile, which can be readily corrected. Without the variance in the ZCT profile, the deformations are higher-order, such as higher than quadratic, which cannot be readily corrected.

In some aspects, at least one of the ZCT profile and ZCT slope profile vary in a region adjacent to an edge of the reticle or reticle blank. It has been found that varying the ZCT profile and/or ZCT slope profile adjacent to an edge of the reticle or reticle blank is advantageous to reduce the non-correctable deformations. Without being bound by scientific theory, it is believed that the deformations in the edge of the reticle or reticle blank may be altered in situ when supported by the reticle clamp. By varying the ZCT profile and or ZCT slope profile as described, the deformations at the edge of the reticle or reticle blank can be controlled.

In some aspects, the ZCT of the reticle or reticle blank is higher at at least one border of the reticle or reticle blank. By having the ZCT higher at the border of the reticle, it has been found that there can be an overlay improvement of over 35%. According to some aspects, the ZCT of the reticle or reticle blank has a range of around ±1° C., around ±2° C., around ±3° C., around ±4° C., around, ±5° C., around ±6° C., around ±7° C., around ±8° C., around ±9° C., or around ±10° C. By having a ZCT with a larger range, the reticle or reticle blank is dimensionally stable over a greater range of temperatures. In some aspects, the ZCT slope may be from around 0.5 ppb/K2 to around 2.5 ppb/K2. The ZCT may be from around 1.0 ppb/K2 to around 2.0 ppb/K2. In some aspects, the ZCT profile and/or the ZCT slope profile has at least one axis of symmetry. The axis of symmetry may be the y-axis, x-axis, and/or z-axis.

In some aspects, a reticle clamp may include a reticle as described herein.

In some aspects, a lithographic apparatus can include a reticle or reticle clamp according to the first or second aspects of the present disclosure. The lithographic apparatus can be a deep ultraviolet (DUV) or an extreme ultraviolet (EUV) lithographic apparatus.

In some aspects, a method of mitigating non-correctable deformations in a reticle or reticle blank can include providing a reticle or reticle blank having at least one of a ZCT profile and a ZCT slope profile that is non-uniform across the reticle or reticle blank. With a non-uniform ZCT profile and/or ZCT slope profile, an amount of non-correctable deformations in a reticle or reticle blank can be reduced, which can reduce overlay errors. The method can include varying at least one of the ZCT profile and ZCT slope profile in a region adjacent to an edge of the reticle or reticle blank.

In some aspects, a method of producing a reticle or reticle blank for a lithography process can include modeling deformation of the reticle or reticle blank under use conditions, based on the deformation modeling, calculating a ZCT profile, and/or a ZCT slope profile of the reticle or reticle blank to decrease any modelled non-correctable deformations, optionally repeating these steps until the modelled non-correctable deformations have been reduced to a predetermined level; outputting an optimized ZCT profile and/or a ZCT slope profile of the reticle or reticle blank; and producing a reticle or reticle blank having the optimized ZCT profile and/or a ZCT slope profile.

According to some aspects, the non-correctable deformations in a reticle or reticle blank can be reduced by adjusting the ZCT profile and/or ZCT slope profile across the reticle or reticle blank. In other words, the ZCT and ZCT slope can be different in different parts of the reticle or reticle blank. By modeling the deformation of the reticle or reticle blank, non-correctable deformations can be reduced by adjusting the ZCT profile and/or ZCT slope profile, and subsequently a reticle or reticle blank with the desired ZCT profile and/or ZCT slope profile can be produced.

In some aspects, a method comprises determining a target operating temperature of a reticle during use; adjusting a thermal expansion (TE) property of the reticle based on the target operating temperature of the reticle; and exposing the reticle to radiation to perform a manufacturing process.

In some aspects, the TE property of reticle can be a coefficient of thermal expansion (CTE) of the reticle, which can be adjusted to approximate the target operating temperature of the reticle during use. In some aspects, the CTE can be an instantaneous CTE that is adjusted to be approximately zero near the target operating temperature of the reticle, or an average CTE that can be adjusted to be approximately zero between an initial temperature of the reticle and the target operating temperature of the reticle. In some aspects, the CTE can be spatially tuned to minimize short duration effects, intra-wafer effects, and/or inter-field effects.

In some aspects, the TE property of the reticle can be a ZCT of the reticle. In some aspects, the reticle can be written at a temperature approximating the ZCT of the reticle. In some aspects, adjusting the TE property of the reticle comprises adjusting a TE property of each of a plurality of zones of the reticle, each zone of the plurality of zones of the reticle having a different ZCT.

In some aspects, a method of manufacturing a reticle comprises determining a target operating temperature of the reticle during use, determining a desired thermal expansion (TE) property of the reticle based on the target operating temperature of the reticle, and fabricating the reticle to approximate the desired thermal expansion (TE) of the reticle.

Further features of various aspects of the present disclosure are described in detail below with reference to the accompanying drawings. It is noted that the present disclosure is not limited to the specific aspects described herein. Such aspects are presented herein for illustrative purposes only.

Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1 depicts a lithographic apparatus, according to some aspects.

FIG. 2A shows a reflective lithographic apparatus, according to some aspects.

FIG. 2B shows a transmissive lithographic apparatus, according to some aspects.

FIG. 2C shows a lithographic cell, according to some aspects.

FIG. 3 shows deformation of a reticle in a reticle clamp, according to some aspects.

FIGS. 4A and 4B show the deformation of a reticle with nominal uniform ZCT and the deformation of a reticle with a quadratic ZCT profile in the y-direction, according to some aspects.

FIG. 5 shows one exemplary embodiment of a reticle or reticle blank, according to some aspects.

FIGS. 6 and 7 show a reticle stage, according to some aspects.

FIGS. 8 and 9 show a reticle exchange apparatus, according to some aspects.

FIG. 10 shows a flowchart of a method of manufacturing a reticle, according to some aspects.

FIG. 11 shows a schematic representation of a reticle, according to some aspects.

FIG. 12 shows a flowchart of a method of manufacturing a reticle, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

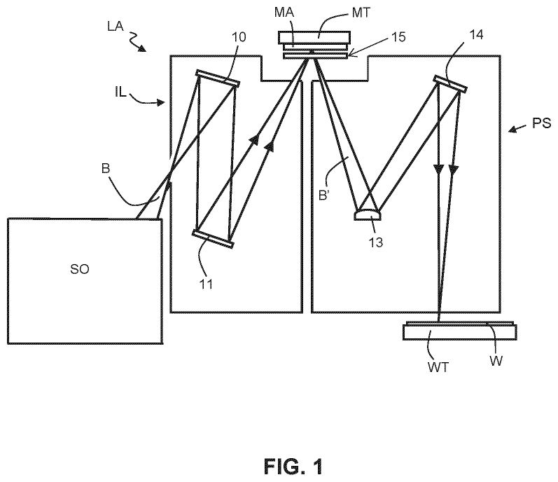

FIG. 1 shows a lithographic system according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, a pellicle 15 is depicted in the path of the radiation and protecting the patterning device MA. It will be appreciated that the pellicle 15 may be located in any required position and may be used to protect any of the mirrors in the lithographic apparatus. The patterning device MA may be referred to as the reticle. The support structure MT may be referred to as the reticle stage.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type that may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 that are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation source SO shown in FIG. 1 may include components that are not illustrated. For example, a spectral filter may be provided in the radiation source. The spectral filter may be substantially transmissive for EUV radiation but substantially blocking for other wavelengths of radiation such as infrared radiation.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

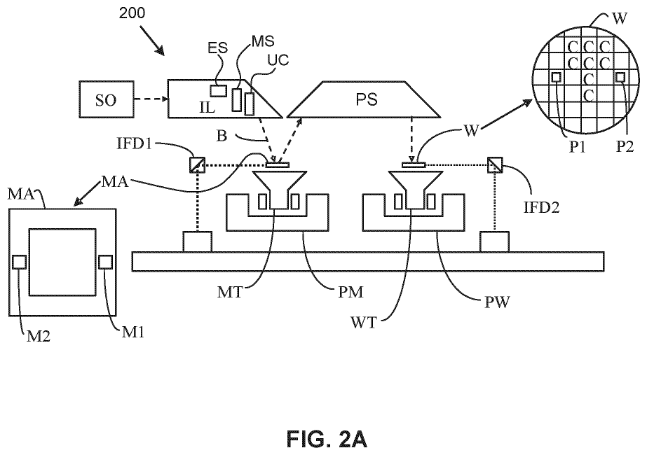

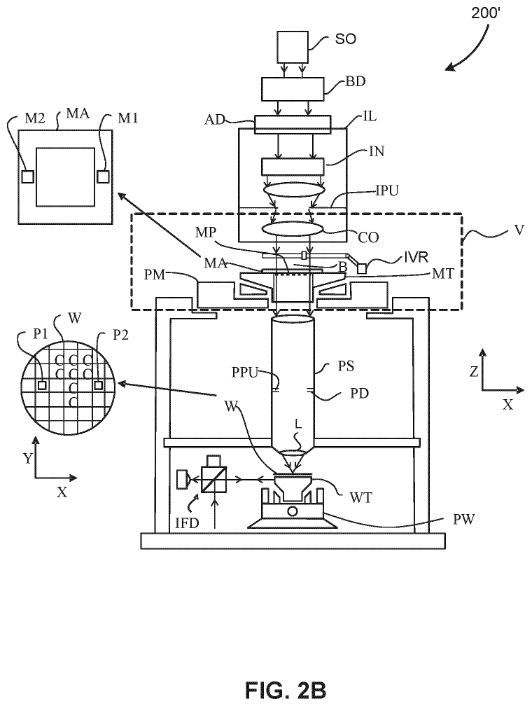

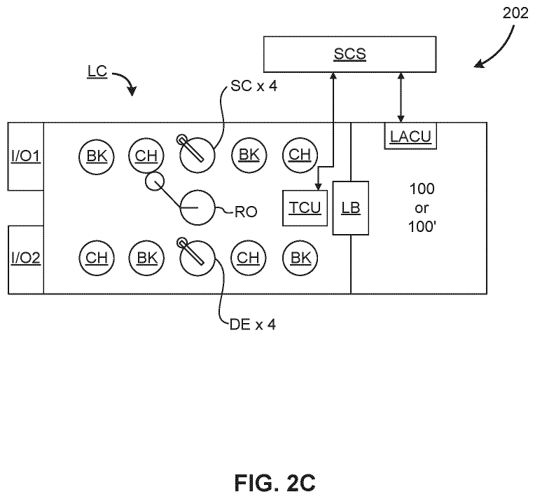

FIGS. 2A and 2B show a lithographic apparatus 200 and a lithographic apparatus 200′, respectively, in which aspects of the present disclosure can be implemented. Lithographic apparatus 200 and lithographic apparatus 200′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 200 and 200′ also have a projection system PS configured to project a pattern imparted to the radiation beam B by patterning device MA onto a target portion (for example, comprising one or more dies) C of the substrate W. In lithographic apparatus 200, the patterning device MA and the projection system PS are reflective. In lithographic apparatus 200′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 200 and 200′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 200′ of FIG. 2B) or reflective (as in lithographic apparatus 200 of FIG. 2A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 200 and/or lithographic apparatus 200′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 2A and 2B, the illuminator IL receives a radiation beam from a radiation source SO. The source SO and the lithographic apparatus 200, 200′ can be separate physical entities, for example, when the source SO is an excimer laser. In such cases, the source SO is not considered to form part of the lithographic apparatus 200 or 200′, and the radiation beam B passes from the source SO to the illuminator IL with the aid of a beam delivery system BD (in FIG. 2B) including, for example, suitable directing mirrors and/or a beam expander. In other cases, the source SO can be an integral part of the lithographic apparatus 200, 200′, for example, when the source SO is a mercury lamp. A radiation system can comprise the source SO, the illuminator IL, and/or the beam delivery system BD.

The illuminator IL can include an adjuster AD (in FIG. 2B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 2B), such as an integrator IN and a condenser CO. The illuminator IL can be used to condition the radiation beam B to have a desired uniformity and intensity distribution in its cross section.

Referring to FIG. 2A, the radiation beam B is incident on the patterning device (for example, mask) MA, which is held on the support structure (for example, mask table) MT, and is patterned by the patterning device MA. In lithographic apparatus 200, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 2B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 2B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 200 and 200′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 200 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 200′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

### Example Lithographic Cell

FIG. 2C shows a lithographic cell 202, also sometimes referred to a lithocell or cluster, according to some aspects. Lithographic apparatuses 200 or 200′ can form part of lithographic cell 200. Lithographic cell 202 can also include one or more apparatuses to perform pre- and post-exposure processes on a substrate. Conventionally, these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 200 or 200′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Reticle Deformation

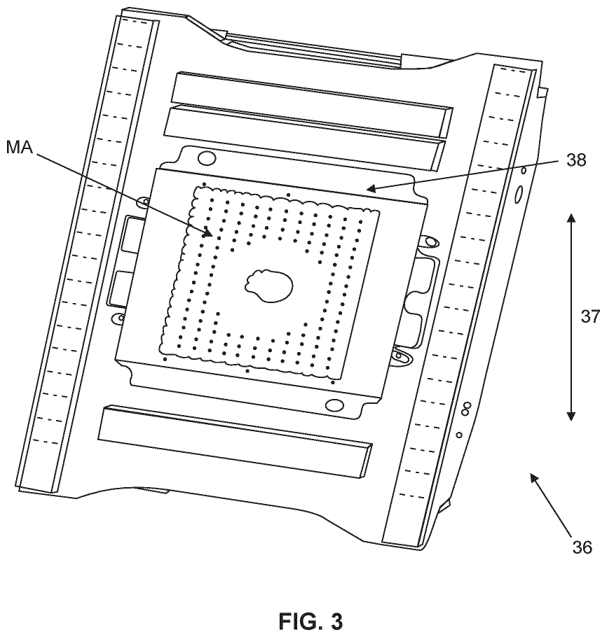

FIG. 3 depicts the deformation of a reticle MA in a reticle clamp 36. The least amount of deformation of the reticle MA is in the center of the reticle MA. At the edges of the reticle in the y-direction 37, the deformation is the greatest. In some embodiments, the reticle may be loaded at around ambient temperature and when imaging of the reticle starts, the outer edge of the reticle expands as the area cools down to the operating temperature of the clamp 38 whereas the imaging area of the reticle expands as the radiation beam heats it up to a steady state temperature. The outer edge remains in the expanded cold state. The further away the reticle edge is from the zero crossing temperature, the bigger the strain in this area of the reticle. This differential strain causes non-correctable deformations.

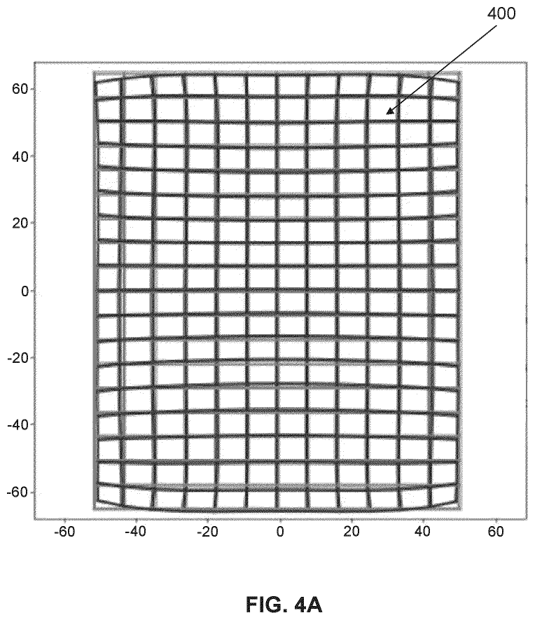

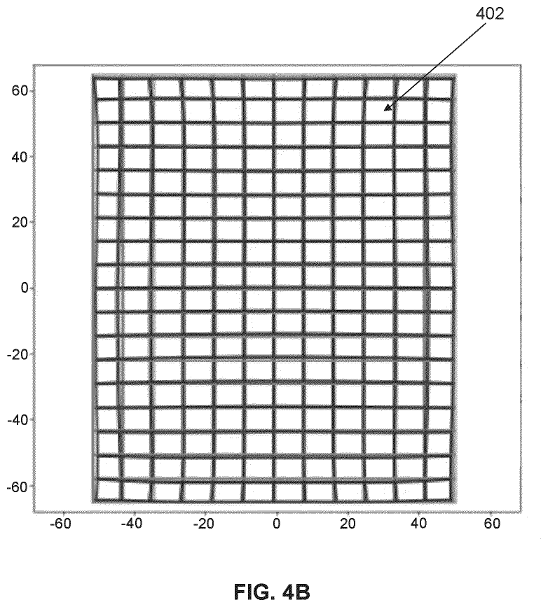

FIGS. 4A and 4B depict the deformation of a reticle 400 with nominal uniform ZCT and the deformation of a reticle with a quadratic ZCT profile in the y-direction. In FIG. 4A, with a reticle 400 having a uniform ZCT profile and/or ZT slope profile, at the y-borders, namely the top and bottom of the grid, there is a greater degree of deformation. Such deformation is not correctable by normal alignment techniques. In such a case, the overlay can be optimized to around 0.5 nm. FIG. 4B depicts a reticle 402 according to the present disclosure which is non-uniform. The deformations are decreased at the y-borders, which allows the overlay to be optimized to around 0.31 nm.

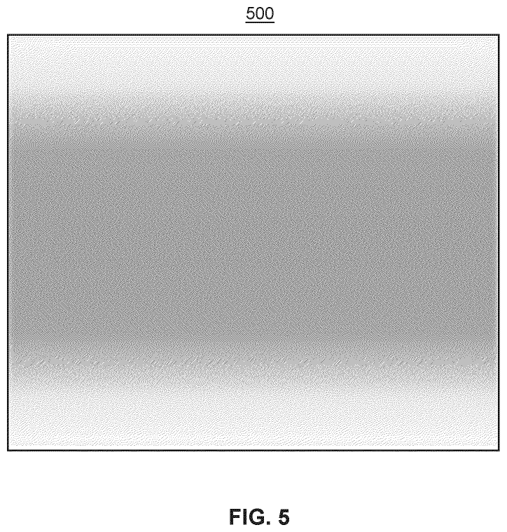

FIG. 5 depicts one exemplary embodiment of a reticle 500 in accordance with the present disclosure. Reticle 500 may be a reticle blank. In the schematic shown in FIG. 5, the ZCT of the reticle is depicted with the lowest ZCT being provided in the middle portion of the reticle and the ZCT increasing at the −Y and +Y reticle borders. There may be an axis of symmetry along both the y-axis and along the x-axis.

By providing a reticle or reticle blank with a non-uniform ZCT profile or ZCT slope profile, the amount of non-correctable deformations can be reduced when in use, which improves the overlay accuracy of the apparatus in which it is used. Previously, reticles and reticle blanks were manufactured with the intention of providing a uniform ZCT profile and/or ZCT slope profile across the extent of the reticle or reticle blank.

### Example Reticle Stage

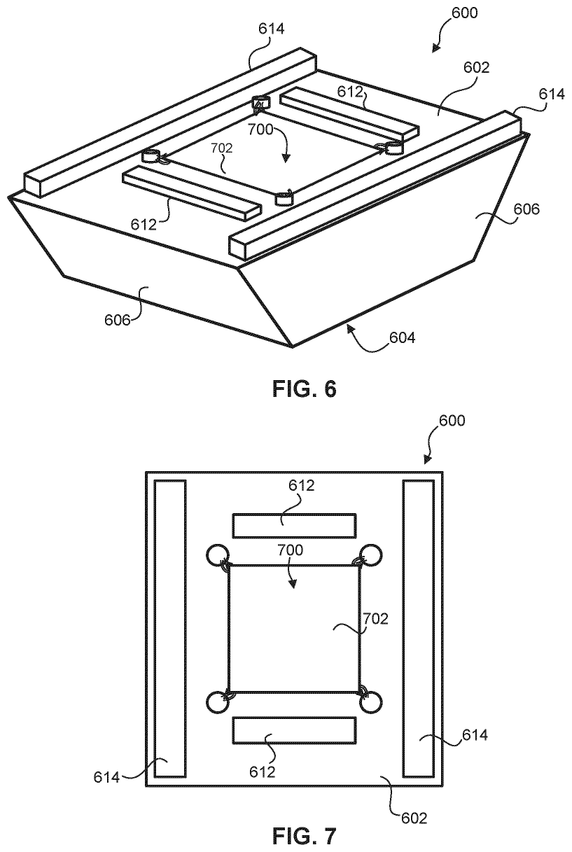

FIGS. 6 and 7 show a reticle stage 600, according to some aspects. Reticle stage 600 can include top stage surface 602, bottom stage surface 604, side stage surfaces 606, and clamp 700. In some aspects, reticle stage 600 with clamp 700 can be implemented in lithographic apparatus LA. For example, reticle stage 600 can be support structure MT in lithographic apparatus LA. In some aspects, clamp 700 can be disposed on top stage surface 602. For example, as shown in FIG. 6, clamp 700 can be disposed at a center of top stage surface 602 with clamp frontside 702 facing perpendicularly away from top stage surface 602.

In some lithographic apparatuses, for example, lithographic apparatus LA, a reticle stage 600 with a clamp 700 can be used to hold and position a reticle for scanning or patterning operations. In one example, the reticle stage 600 can rely on powerful drives, large balance masses, and heavy frames to support it. In one example, the reticle stage 600 can have a large inertia and can weigh over 500 kg to propel and position a reticle weighing about 0.5 kg. To accomplish reciprocating motions of a reticle, which are typically found in lithographic scanning or patterning operations, accelerating and decelerating forces can be provided by linear motors that drive the reticle stage 600.

In some aspects, as shown in FIGS. 6 and 7, reticle stage 600 can include first encoder 612 and second encoder 614 for positioning operations. For example, first and second encoders 612 and 614 can be interferometers. First encoder 612 can be attached along a first direction, for example, a transverse direction (i.e., X-direction) of reticle stage 600. Second encoder 614 can be attached along a second direction, for example, a longitudinal direction (i.e., Y-direction) of reticle stage 600. In some aspects, as shown in FIGS. 6 and 7, first encoder 612 can be orthogonal to second encoder 614.

As shown in FIGS. 6 and 7, reticle stage 600 can include clamp 700. Clamp 700 is configured to hold reticle 808 in a fixed plane on reticle stage 600. Clamp 700 includes clamp frontside 702 and can be disposed on top stage surface 602. In some aspects, clamp 700 can use mechanical, vacuum, electrostatic, or other suitable clamping techniques to hold and secure an object. In some aspects, clamp 700 can be an electrostatic clamp, which can be configured to electrostatically clamp (i.e., hold) an object, for example a reticle, in a vacuum environment. For EUV generation performed in a vacuum environment, it can be difficult to use vacuum clamps to clamp a mask or reticle. Instead, electrostatic clamp(s) can be used. For example, clamp 700 can include an electrode, a resistive layer on the electrode, a dielectric layer on the resistive layer, and burls projecting from the dielectric layer. In use, a voltage can be applied to clamp 700, for example, several kV. And current can flow through the resistive layer, such that the voltage at an upper surface of the resistive layer will substantially be the same as the voltage of the electrode and generate an electric field. Also, a Coulomb force, attractive force between electrically opposite charged particles, will attract an object to clamp 700 and hold the object in place. In some aspects, clamp 700 can be a rigid material, for example, a metal, a dielectric, a ceramic, or a combination thereof.

### Example Reticle Exchange Apparatus

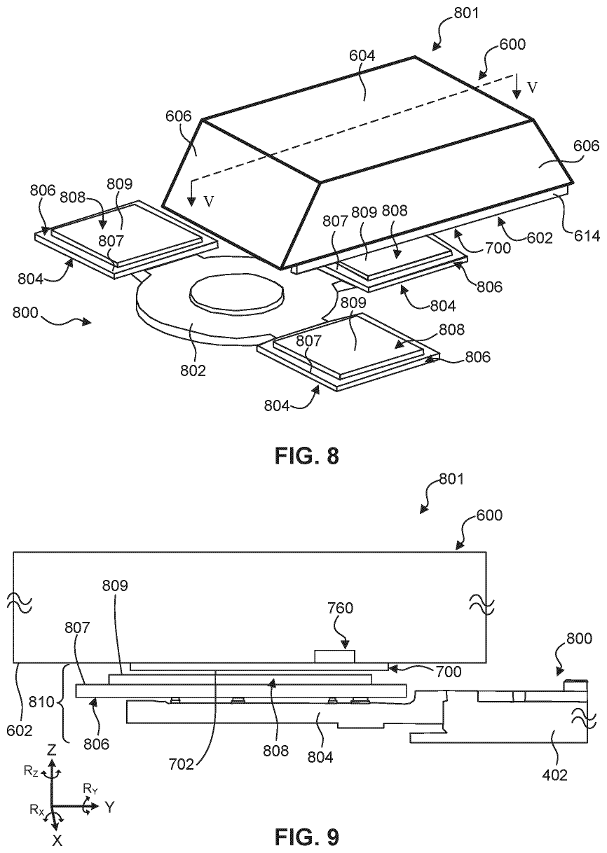

FIGS. 8 and 9 show a reticle exchange apparatus 801, according to some aspects. Reticle exchange apparatus 801 can be configured to minimize reticle exchange time, particle generation, and contact forces or stresses from clamp 700 and/or reticle 808 to reduce damage to clamp 700 and reticle 808 and increase overall throughput in a reticle exchange process, for example, in a lithographic apparatus LA.

As shown in FIGS. 8 and 9, reticle exchange apparatus 801 can include reticle stage 600, clamp 700, and in-vacuum robot 800. In-vacuum robot 800 can include reticle handler 802.

In some aspects, reticle handler 802 can be a rapid exchange device (RED), which is configured to efficiently rotate and minimize reticle exchange time. For example, reticle handler 802 can save time by moving multiple reticles from one position to another substantially simultaneously, instead of serially.

In some aspects, as shown in FIG. 8, reticle handler 802 can include one or more reticle handler arms 804. Reticle handler arm 804 can include reticle baseplate 806. Reticle baseplate 806 can be configured to hold an object, for example, reticle 808.

In some aspects, reticle baseplate 806 can be an extreme ultraviolet inner pod (EIP) for a reticle. In some aspect, reticle baseplate 806 includes reticle baseplate frontside 807, and reticle 808 includes reticle backside 809.

In some aspects, as shown in FIGS. 8 and 9, reticle baseplate 806 can hold reticle 808 such that reticle baseplate frontside 807 and reticle backside 809 each face top stage surface 602 and clamp frontside 702. For example, reticle baseplate frontside 807 and reticle backside 809 can be facing perpendicularly away from top stage surface 602 and clamp frontside 702.

As shown in FIG. 9, reticle exchange apparatus 801 can include reticle exchange area 810, which is the cross-sectional area between clamp 700, reticle 808, reticle baseplate 806, and reticle handler arm 804 during a reticle exchange process.

In some aspects, as shown in FIG. 8, reticle handler arms 804 can be arranged symmetrically about reticle handler 802. For example, reticle handler arms 804 can be spaced from each other by about 90 degrees, 120 degrees, or 180 degrees. In some aspects, reticle handler arms 804 can be arranged asymmetrically about reticle handler 802. For example, two reticle handler arms 804 can be spaced from each other by about 135 degrees, while another two reticle handler arms 804 can be spaced from each other by about 90 degrees.

In one example, during a reticle exchange process, reticle handler arm 804 of reticle handler 802 positions reticle 808 on reticle baseplate 806 towards clamp 700 in reticle exchange area 810. As described above, a reticle handoff from reticle handler 802 to clamp 700 includes an unknown reticle position offset, which includes a reticle vertical distance offset (i.e., Z-direction offset) and a reticle tilt offset (i.e., R_{X} offset and R_{Y} offset). Tilt or excessive non-alignment between clamp 700 and reticle 808 can be a source of particle generation and can damage reticle 808 or clamp 700 over time. Reticle backside 809 and clamp frontside 702 can be in coplanar alignment for a final handoff. Despite calibration, variations still exist due to reticle mechanical and positioning tolerances, which can lead to high corner impacts and unpredictable first contact points between clamp 700 and reticle 808.

In one example, the reticle exchange process can involve lowering reticle stage 600 with clamp 700, which starts far away from reticle handler 802, as close to reticle 808 as possible until clamp 700 contacts reticle 808 to account for all possible offsets and/or tilts. During a reticle exchange process, reticle stage 600 with clamp 700 can be adjusted in a multi-stage movement (e.g., long stroke stage (coarse motion), short stroke stage (fine motion)).

In some aspects, as shown in FIG. 9, reticle exchange apparatus 801 can include clamp controller 760. Clamp controller 760 can be coupled to clamp 700 and be configured to control a position of clamp 700. For example, clamp controller 760 can be configured to control reticle stage 600 to allow compliant movement of clamp 700. In some aspects, clamp controller 760 can be coupled to servo motors or servo actuators (i.e., X-direction, Y-direction, Z-direction, R_{X}, R_{Y}, R_{Z}) of reticle stage 600 and/or clamp 700. For example, clamp controller 760 can control translations of reticle stage 600 with clamp 700 along an x-axis, y-axis, and z-axis (i.e., X-direction, Y-direction, Z-direction) and rotations about the x-axis, y-axis, and z-axis (i.e., R_{X}, R_{Y}, R_{Z}), where the x-axis, y-axis, and z-axis are orthogonal coordinates.

### Reticle Thermal Strain and Thermal Expansion Properties

Thermal strain in a reticle can be modeled as:

$$ϵ ( z ) = {\int }_{{T}_{0} ( z )}^{{T}_{f} ( z )} CTE ( z , T ) dT ,$$

where ϵ(z) is the thermal strain of the reticle at a position along an arbitrary direction (z) of the reticle; T₀(z) and T_{f}(z) are the initial and final temperatures of the reticle through the exposure or process, respectively; and CTE(z,T) is the coefficient of thermal expansion (CTE) of the reticle.

In some aspects, a reticle can be comprised of a material having an appropriate ZCT and other TE properties. These TE properties can be selected to vary as a function of position, in a way to reduce the amount of thermal strain. For example, the reticle can be comprised of ultra-low expansion (ULE) glass, with variable TE properties through its thickness (in the z-direction). In the case of such reticles, and for small temperature variations from ZCT (denoted as T_{ZC} in the following equations), the CTE of the reticle along the arbitrary z-direction of the reticle can be approximated as a linear function of temperature:

$$CTE ( z ) = α ( z ) * ( T - {T}_{zc} ( z ) ) ,$$

where α(z) can be determined experimentally or by simulation as a function (or value). A skilled artisan will understand that this linear approximation of CTE variation of the reticle could also be approximated as a non-linear function according to some aspects without departing from the invention.

Taking the above equations together, the thermal strain of the reticle at an arbitrary z-position, according to some aspects, can be given as:

$$ϵ ( z ) = α ( z ) {\int }_{{T}_{0} ( z )}^{{T}_{f} ( z )} ( T - {T}_{zc} ( z ) ) dT .$$

Integrating over T from T₀(z) to T_{f}(z), the above equation yields:

$$ϵ ( z ) = α ( z ) * [ ( \frac{{{T}_{f} ( z )}^{2} - {{T}_{0} ( z )}^{2}}{2} ) - {T}_{zc} ( z ) * ( {T}_{f} ( z ) - {T}_{0} ( z ) ) ] ,$$

which can be rewritten as

$$ϵ ( z ) = α ( z ) * [ ( \frac{{T}_{f} ( z ) - {T}_{0} ( z )}{2} - {T}_{zc} ( z ) ) * ( {T}_{f} ( z ) - {T}_{0} ( z ) ) ] ,$$

According to the above equation, the thermal strain ϵ of the reticle at an arbitrary z-position becomes zero under two possible conditions:

$${T}_{f} ( z ) = {T}_{0} ( z ) . \qquad ( 1 )$$

$${T}_{zc} ( z ) = \frac{{T}_{f} ( z ) + {T}_{0} ( z )}{2} , \qquad ( 2 )$$

or

The above condition (2) means that T_{zc} (as a function of position along the arbitrary z-direction) is equal to the average of the initial and final temperatures of the reticle. That is, to satisfy condition (2) or to minimize the thermal strain, the T_{zc} at a point of the reticle should be adjusted to approximately equal the average of the temperature of that point of the reticle at the time of loading and the time of use. This condition can be applied in inter-field and intra-wafer processing, where short duration effects can largely contribute to thermal strain in the reticle. For example, during wafer processing, the reticle can be exposed repeatedly on the same wafer, at different spots or “fields,” and this short-term heating of the reticle can create thermal strain in the reticle. Even if the above expression (2) is not identically zero, the thermal strain can be reduced (from what the value would be otherwise) by approximate matching of the local zero crossing temperature, and/or matching the average TE properties in some finite region of the reticle to the average of the loading and usage temperature of the reticle. One of ordinary skill in the art will appreciate that this example could be extended to variations in the x- and y-directions.

By way of illustration, in a non-limiting example, a reticle can have an initial temperature of 22° C., the front face of the reticle can be heated to a final temperature of 50° C. by exposure to radiation during an intra-wafer lithography process, while the back face of the reticle is held at 22° C. due to cooling from the chuck or clamp. In this example, the above condition (2) would mean that the thermal strain ϵ of the back face of the reticle is zero if T_{zc} of the back face is 22° C., because

$$\frac{( 22 ° C . + 22 ° C . )}{2} = 22 ° C .$$

Similarly, the above condition (2) would mean that the thermal strain ϵ of the front face of the reticle is zero if the T_{zc} of the front face is 36° C., because

$$\frac{( 22 ° C . + 50 ° C . )}{2} = 36 ° C .$$

In this example, the T_{zc} of the reticle should range from 36° C. at the front face to 22° C. at the back face. A skilled artisan would understand that achieving the full range of such a spatially varying T_{zc} may be constrained by practical considerations. Nonetheless, a lower thermal strain E of the reticle can be realized by approximating such a spatially varying T_{zc}. The following description provides methods for achieving a reticle having such spatially varying TE properties.

### Example Spatial Variation of Reticle Thermal Expansion Property

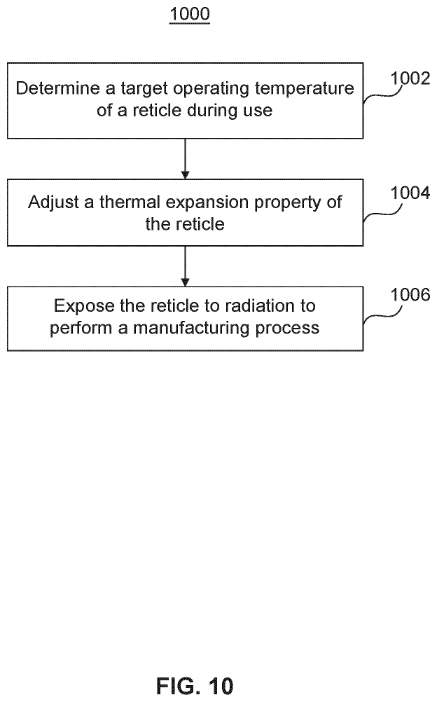

As explained above, one way to minimize the thermal strain ϵ of a reticle is to form a reticle to have a thermal expansion (TE) property that spatially varies across the reticle. FIG. 10 shows a flowchart of a method for spatially varying a TE property of a reticle, according to some aspects. At step 1002, a target operating temperature of a reticle during use can be determined. At step 1004, a thermal expansion (TE) property of the reticle can be adjusted. The TE property of the reticle can be adjusted based on one or more of the following methods. At step 1006, the reticle can be exposed to radiation to perform a manufacturing process.

In particular, in step 1002, a target operating temperature of a reticle during use can be determined. The target operating temperature of the reticle can be determined using any convenient method. For example, in some aspects, the target operating temperature of the reticle can be determined by directly measuring an operating temperature of a precursor reticle or by directly measuring an operating temperature of a reticle used during a previous manufacturing process. In some aspects, the target operating temperature of the reticle can be determined by modeling one or more target operating conditions of the reticle, such as a predicted dose of the radiation on the reticle, the approximate absorption pattern of the reticle, the method of holding the reticle, the cooling environment for the reticle, or the like. In some aspects, the target operating temperature can be determined by looking up a stored target operating temperature corresponding to a target wafer manufacturing process. In some aspects, the target operating temperature of the reticle can be based at least in part on a predicted loading temperature of the reticle.

At step 1004, one or more TE properties of the reticle can be adjusted based on the target operating temperature of the reticle determined in step 1002. In some aspects, the TE property of the reticle can be adjusted to approximate the target operating temperature of the reticle during use. In some aspects, the TE property of the reticle can be adjusted based on an average value between an initial temperature of the reticle into a processing apparatus and the target operating temperature of the reticle during use. As a non-limiting example, the initial temperature of the reticle can be a temperature of the reticle when it is loaded into an apparatus for a manufacturing process. According to some aspects, the TE property of the reticle can be spatially tuned to minimize short duration effects. For example, a TE property of the reticle can be adjusted that that the TE property increases or decreases across one or more of a length, width, or height of the reticle, or a TE property of the reticle can be adjusted to have a peak at a particular location in the reticle. In some aspects, minimizing short duration effects can include minimizing one or both of inter-field effects and intra-wafer effects, as discussed above. In some aspects, the TE property that is adjusted can be a coefficient of thermal expansion (CTE), a zero-crossing temperature (T_{zc}) of the reticle, or other similar thermal property.

According to some aspects, the CTE property can be an instantaneous CTE of the reticle that is the derivative of the thermal strain ϵ at a specific temperature. In some aspects, the instantaneous CTE can be adjusted to be approximately zero near the target operating temperature of the reticle. According to some aspects, the CTE property of the reticle can be an average CTE of the reticle for a particular temperature range. In some aspects, the CTE can be adjusted to be between an initial temperature of the reticle and the target operating temperature of the reticle. As a non-limiting example, the CTE can be adjusted be approximately a midpoint between the initial temperature of the reticle and the target operating temperature of the reticle.

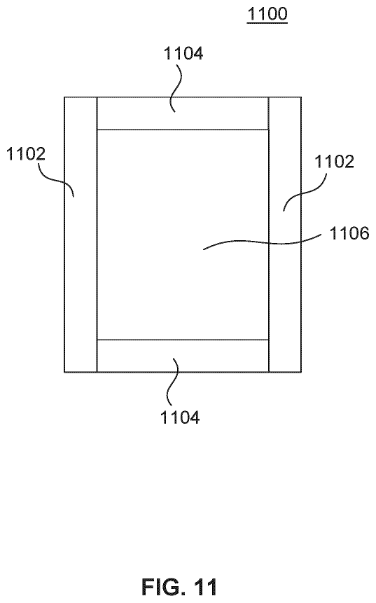

FIG. 11 shows a non-limiting schematic example of a reticle 1100 having spatially-varying TE properties, according to some aspects. As shown in FIG. 11, each zone 1102, 1104, and 1106 of reticle 1100 has a different TE property. According to some aspects, a TE property of each zone can be determined by determining an expected or target operating temperature of the respective zone.

For example, zone 1106 in reticle 1100 can correspond to an image field zone configured to be exposed to radiation during wafer processing. In some examples, zone 1106 can be directly exposed to radiation used for wafer processing.

In some aspects, zone(s) 1102 can correspond to an unheated zone that is configured to not be exposed to radiation during wafer processing. In some examples, zone(s) 1102 may not receive any radiation during wafer processing, or may receive a lower dose of radiation than zone 1106. For this reason, the expected operating temperature of zone(s) 1102 can, in some aspects, be lower than the expected operating temperature of zone 1106. Thus, according to some aspects, the T_{zc} of zone(s) 1102 can be adjusted to be lower than T_{zc} of zone 1106, so that T_{zc} for each zone approximately equals the average temperature of the respective zone. Creating separate zones each having a different T_{zc} corresponds to imposing condition (2), as explained above, in a spatially-varying manner, based on the expected operating temperature of each zone. In other words, because zone 1106 and zone(s) 1102 may be expected to have different average operating temperatures, the T_{zc} may be adjusted individually for each zone, so that thermal strain for each zone is minimized.

Likewise, zone(s) 1104 can correspond to an actively cooled zone of the reticle, according to some aspects. For example, zone(s) 1104 can be actively cooled by contact with a clamp or chuck that is actively cooled. In this example, zone(s) 1104 can be expected to have an operating temperature that is lower than that of image zone 1106 and unheated zone(s) 1102. According to some aspects, a T_{zc} of actively cooled zone(s) 1104 can be adjusted be lower than T_{zc} for each of image zone 1106 and unheated zone(s) 1102 because the average temperature of actively cooled zone 1104 can be expected to be lower than the average temperature for each of image zone 1106 and unheated zone(s) 1102. Thus, according to some aspects, reticle 1100 can comprise three zones, each having a different T_{zc}.

It should be understood that, while FIG. 11 shows reticle 1100 having different zones 1102, 1104, and 1106, three different zones are shown merely for illustrative purposes, and the invention is not limited to a reticle having three different zones. In practice, a reticle could have n number of zones, where n is any integer greater than or equal to two. The number of zones n in the reticle can be determined by practical considerations, such as a number of contact points between the reticle and clamp(s), the dose of radiation applied to the reticle, the pattern of the radiation applied to the reticle, and the like.

Zones 1102, 1104, and 1106 (and any other zones) can have any shape that corresponds to a desired profile of a TE property. In some aspects, the shape of one or more zones can be determined by a shape of the processing radiation, a clamp or chuck used to hold the reticle, or the like. FIG. 11 shows zones 1102, 1104, and 1106 having substantially rectangular cross-sections, but the invention is not limited to such shapes. As non-limiting examples, zones 1102, 1104, and 1106 could have triangular, circular, or ellipsoidal cross-sections. In some aspects, zones 1102, 1104, and 1106 have shapes that substantially correspond to regular polygons, but zones 1102, 1104, and 1106 could also have shapes that correspond to irregular polygons or any other two-dimensional shape. Moreover, as discussed below, zones 1102, 1104, and 1106 are not limited to one or two dimensions, but can extend in all three spatial directions, and therefore could also have shapes corresponding to any three-dimensional shape. In some aspects, a length of a cross-section of a zone can change along one or more directions of the reticle. As a particular non-limiting example, the cross-section of one or more zones may increase or decrease along a thickness direction of the reticle. This example is merely illustrative, and zones having cross-sections changing along any direction can be created without departing from the invention. In addition, the changes of such zones can be done in any way that optimizes the TE property of the reticle, such as, for example, step-wise, or changing linearly or curvilinearly. A skilled artisan will appreciate that the shape of each zone can be individually optimized based on the desired TE property of the reticle.

In addition, while FIG. 11 shows that reticle 1100 has a TE property that varies across the length and width of reticle 1100, it should be understood that, according to some aspects, a TE property of reticle 1100 could likewise be varied across a thickness of reticle 1100, according to some aspects. In some aspects, the TE properties of a reticle can be varied across one, two, or all three spatial dimensions of the reticle.

According to some aspects, the TE property of the reticle can be adjusted by spatially varying one or more properties of the reticle. For example, one way of spatially varying the TE property of the reticle according to some aspects can be change a thickness of a reticle material across one or more spatial dimensions of the reticle. In particular, a thickness of one or more regions of the reticle can be adjusted to reduce a temperature gradient across the reticle and thus reduce the thermal strain across the reticle.

Another way of spatially varying the TE property of the reticle in some aspects can be to vary a material composition across one or more spatial directions of the reticle. As a specific example, a reticle in some aspects can be composed of, for example, silicon oxide SiO₂ doped with titanium oxide TiO₂. The doping concentration of the TiO₂ may be increased or decreased in certain regions of the reticle, to adjust up or down the TE property of the reticle. As another example, a similar effect could be realized in some aspects by laminating together layers with different TE properties, such as ZCT. In some embodiments, the different TE properties could be provided by varying the makeup of the layers, for example, the proportions of SiO₂ and TiO₂). In some aspects, thin layers of approximately 1 mm or less thickness can be laminated together so that the TE property through the laminated layers approximates a desired value and/or so that the TE property changes through the layers along the lamination direction. Depending on manufacturing and other considerations, thicker or thinner layers may be preferred. As another non-limiting example, a reticle can be composed primarily of ultra-low expansion (ULE) glass, according to some aspects. In this example, the TE property of the reticle can be varied by using another material, such as, for example, cordierite or other similar materials, to adjust the TE property along the lamination direction. In some embodiments, different layers could be laminated together by using an adhesive (e.g. epoxy) between the layers or by using optical contacting.

The above examples are not limiting of the invention, and it should be understood that the TE property can be changed by alloying, mixing, doping, or laminating two or more materials with different values for the same TE property. In this regard, it is not required that the materials have different compositions, but it is to be understood that the TE property can also be spatially varied by treating one material to have different TE properties in different regions by, for example, grain boundary engineering, heat treatment, or the like.

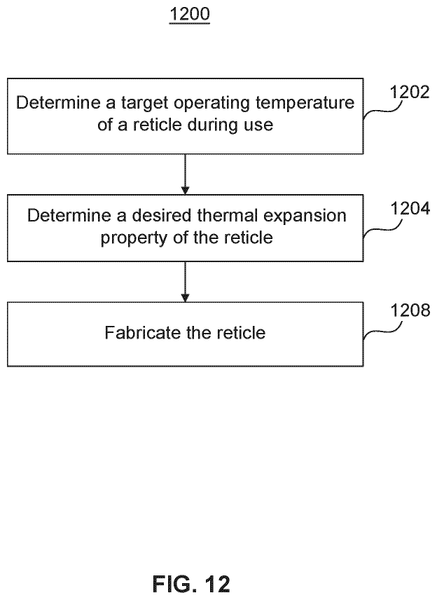

FIG. 12 shows a flowchart for a method of fabricating a reticle according to some aspects. At step 1202, a target operating temperature of a reticle during use can be determined by, for example, measurement and/or modeling. The target operating temperature of the reticle can be determined using any of the methods discussed above. At step 1204, a desired TE property of the reticle can be determined based on the target operating temperature. The desired TE property of the reticle can be determined using any of the methods discussed above. At step 1206, the reticle can be fabricated to approximate the desired TE property. The reticle can be fabricated using any of the materials and/or methods discussed above, or any appropriate method that is known in the art.

According to some aspects, step 1206 can include a step of writing the reticle at a temperature based on the desired TE property. For example, in some aspects, the reticle can be written at a temperature approximating ZCT of the reticle, as determined based on the target operating temperature of the reticle during use. In some aspects, the reticle can be written at a temperature approximating one of several ZCT corresponding to different zones of the reticle. In some aspects, the reticle can be written at a temperature approximating an average ZCT of the reticle.

The method steps of FIGS. 10 and 12 can be performed in any conceivable order and it is not required that all steps be performed. Moreover, the method steps described above merely reflect an example of steps and are not limiting. That is, further method steps and functions are envisaged based on the aspects described above.

### Further Aspects of the Invention

In some aspects, a reticle or a reticle blank can comprise a low deformation material, wherein the reticle or reticle blank material has a ZCT profile, and a ZCT slope profile, wherein at least one of the ZCT profile and the ZCT slope profile is non-uniform. The reticle of reticle blank can comprise ultra-low expansion glass. The reticle or reticle blank can have x, y, and z-directions, and at least one of the ZCT profile and ZCT slope profile vary in the y-direction. At least one of the ZCT profile and ZCT slope profile can vary in a region adjacent to an edge of the reticle or reticle blank. The ZCT of the reticle or reticle blank can be higher at at least one border of the reticle or reticle blank. The ZCT of the reticle or reticle blank can have a range of around ±1° C., around ±2° C., around ±3° C., around ±4° C., around, ±5° C., around ±6° C., around ±7° C., around ±8° C., around ±9° C., or around ±10° C. The ZCT slope can be from around 0.5 ppb/K2 to around 2.5 ppb/K2. The ZCT profile and/or the ZCT slope profile can have at least one axis of symmetry.

In some embodiments, a reticle clamp can include a reticle as described herein. In some embodiments, a lithographic apparatus can include a reticle or reticle clamp as described herein.

In some embodiments, a method of mitigating non-correctable deformations in a reticle or reticle blank can include providing a reticle or reticle blank having at least one of a ZCT profile and a ZCT slope profile which is non-uniform across the reticle or reticle blank. The method can include varying at least one of the ZCT profile and ZCT slope profile in a region adjacent to an edge of the reticle or reticle blank. The method can include modelling deformation of the reticle or reticle blank under use conditions, based on the deformation modelling, calculating a ZCT profile, and/or a ZCT slope profile of the reticle or reticle blank to decrease any modelled non-correctable deformations, optionally repeating these steps until the modeled non-correctable deformations have been reduced to a predetermined level; outputting an optimized ZCT profile and/or a ZCT slope profile of the reticle or reticle blank; and producing a reticle or reticle blank having the optimized ZCT profile and/or a ZCT slope profile.

In some embodiments, a reticle, reticle blank, lithographic apparatus, or method as described above may be used.

Various embodiments of the present systems and methods are disclosed in the subsequent list of numbered clauses:
1. A method comprising:
   determining a target operating temperature of a reticle during use; and
   adjusting a thermal expansion (TE) property of the reticle based on the target operating temperature of the reticle.
2. The method of clause 1, wherein the adjusting the TE property of the reticle comprises adjusting a coefficient of thermal expansion (CTE) of the reticle.
3. The method of clause 2, wherein:
   the adjusting the TE property comprises adjusting an instantaneous CTE of the reticle; and
   the instantaneous CTE is adjusted to be approximately zero near the target operating temperature of the reticle.
4. The method of clause 2, wherein:
   the adjusting the TE property comprises adjusting an average CTE of the reticle; and
   the average CTE is adjusted to be approximately zero between an initial temperature of the reticle and the target operating temperature of the reticle.
5. The method of clause 2, wherein the CTE and other TE properties of the reticle are adjusted to approximate the target operating temperature of the reticle during use.
6. The method of clause 5, wherein the adjusting the CTE and other TE properties of the reticle comprises spatially tuning the CTE and other TE properties of the reticle to minimize short duration effects.
7. The method of clause 6, wherein the spatially tuning the CTE and other TE properties of the reticle to minimize short duration effects comprises minimizing intra-wafer effects.
8. The method of clause 6, wherein the spatially tuning the CTE of the reticle to minimize short duration effects comprises minimizing inter-field effects.
9. The method of clause 1, wherein the adjusting the TE property of the reticle comprises adjusting a zero-crossing temperature (ZCT) of the reticle.
10. The method of clause 9, wherein the adjusting the TE property of the reticle comprises adjusting a TE property of each of a plurality of zones of the reticle, each zone of the plurality of zones of the reticle having a different ZCT.
11. The method of clause 10, wherein the adjusting the TE property of each of the plurality of zones of the reticle comprises:
   adjusting a TE property of at least one image field zone to have a first ZCT;
   adjusting a TE property of at least one unheated zone to have a second ZCT lower than the first ZCT; and
   adjusting a TE property of at least one cooled zone to have a third ZCT lower than the second ZCT.
12. The method of clause 9, further comprising writing the reticle at a temperature approximating the ZCT of the reticle.
13. The method of clause 1, wherein the adjusting the TE property of the reticle comprises adjusting the TE property of the reticle to approximate an average temperature of a loading temperature of the reticle into an apparatus for the manufacturing process and the target operating temperature of the reticle.
14. The method of clause 1, wherein the adjusting the TE property of the reticle comprises adjusting the TE property along a thickness direction of the reticle.
15. The method of clause 14, wherein the adjusting the TE property of the reticle comprises changing a material composition of one or more materials forming the reticle through the thickness direction of the reticle.
16. The method of clause 14, wherein the adjusting the TE property of the reticle comprises laminating together layers of materials having different thermal expansion properties to form the reticle.
17. The method of clause 14, wherein the adjusting the TE property of the reticle comprises choosing the TE property of the reticle to have a minimum at the target operating temperature.
18. The method of clause 14, wherein the adjusting the TE property of the reticle comprises adjusting the TE property of the reticle to approximate an average of the TE property between an initial temperature of the reticle and the target operating temperature of the reticle.
19. The method of clause 1, wherein the adjusting the TE property of the reticle comprises forming the reticle of cordierite or ultra-low expansion (ULE) glass.
20. A method of manufacturing a reticle, the method comprising:
   determining a target operating temperature of the reticle during use;
   determining a desired thermal expansion (TE) property of the reticle based on the target operating temperature of the reticle; and
   fabricating the reticle to approximate the desired thermal expansion (TE) of the reticle.
21. A reticle configured for use with a lithographic apparatus, the reticle comprising a plurality of zones of the reticle, each zone of the plurality of zones of the reticle having a different ZCT.
22. The reticle of clause 21, wherein the plurality of zones of the reticle comprises:
   at least one image field zone having a first ZCT;
   at least one unheated zone having a second ZCT lower than the first ZCT; and
   at least one cooled zone having a third ZCT lower than the second ZCT.

The terms “radiation,” “beam,” “light,” “illumination,” or the like can be used herein to refer to one or more types of electromagnetic radiation, for example, ultraviolet (UV) radiation (for example, having a wavelength % of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. A method comprising:
determining a target operating temperature of a reticle during use; and
adjusting a thermal expansion (TE) property of the reticle based on the target operating temperature of the reticle.

2. The method of claim 1, wherein the adjusting the TE property of the reticle comprises adjusting a coefficient of thermal expansion (CTE) of the reticle.

3. The method of claim 2, wherein:
the adjusting the TE property comprises adjusting an instantaneous CTE of the reticle; and
the instantaneous CTE is adjusted to be approximately zero near the target operating temperature of the reticle.

4. The method of claim 2, wherein:
the adjusting the TE property comprises adjusting an average CTE of the reticle; and
the average CTE is adjusted to be approximately zero between an initial temperature of the reticle and the target operating temperature of the reticle.

5. The method of claim 2, wherein:
the CTE and other TE properties of the reticle are adjusted to approximate the target operating temperature of the reticle during use; and
the adjusting the CTE and other TE properties of the reticle comprises spatially tuning the CTE and other TE properties of the reticle to minimize short duration effects.

6. The method of claim 5, wherein the spatially tuning the CTE and other TE properties of the reticle to minimize short duration effects comprises minimizing intra-wafer effects; or wherein the spatially tuning the CTE of the reticle to minimize short duration effects comprises minimizing inter-field effects.

7. The method of claim 1, wherein:
the adjusting the TE property of the reticle comprises adjusting a zero-crossing temperature (ZCT) of the reticle;
the adjusting the TE property of the reticle comprises adjusting a TE property of each of a plurality of zones of the reticle, each zone of the plurality of zones of the reticle having a different ZCT;
the adjusting the TE property of each of the plurality of zones of the reticle comprises:
adjusting a TE property of at least one image field zone to have a first ZCT;
adjusting a TE property of at least one unheated zone to have a second ZCT lower than the first ZCT; and
adjusting a TE property of at least one cooled zone to have a third ZCT lower than the second ZCT; and
the method further comprises writing the reticle at a temperature approximating the ZCT of the reticle.

8. The method of claim 1, wherein the adjusting the TE property of the reticle comprises adjusting the TE property of the reticle to approximate an average temperature of a loading temperature of the reticle into an apparatus for the manufacturing process and the target operating temperature of the reticle.

9. The method of claim 1, wherein the adjusting the TE property of the reticle comprises adjusting the TE property along a thickness direction of the reticle.

10. The method of claim 9, wherein the adjusting the TE property of the reticle comprises:
changing a material composition of one or more materials forming the reticle through the thickness direction of the reticle; or
laminating together layers of materials having different thermal expansion properties to form the reticle.

11. The method of claim 9, wherein the adjusting the TE property of the reticle comprises:
choosing the TE property of the reticle to have a minimum at the target operating temperature; or
adjusting the TE property of the reticle to approximate an average of the TE property between an initial temperature of the reticle and the target operating temperature of the reticle.

12. The method of claim 1, wherein the adjusting the TE property of the reticle comprises forming the reticle of cordierite or ultra-low expansion (ULE) glass.

13. A method of manufacturing a reticle, the method comprising:
determining a target operating temperature of the reticle during use;
determining a desired thermal expansion (TE) property of the reticle based on the target operating temperature of the reticle; and
fabricating the reticle to approximate the desired thermal expansion (TE) of the reticle.

14. A reticle configured for use with a lithographic apparatus, the reticle comprising a plurality of zones of the reticle, each zone of the plurality of zones of the reticle having a different ZCT.

15. The reticle of claim 14, wherein the plurality of zones of the reticle comprises:
at least one image field zone having a first ZCT;
at least one unheated zone having a second ZCT lower than the first ZCT; and
at least one cooled zone having a third ZCT lower than the second ZCT.
